(19) United States
(12) Patent Application Publication
(10) Pub. No.: US 2007/0158824 A1
(43) Pub. Date: Jul. 12, 2007

(54) Hybrid composite material substrate

(75) Inventor: Chia-Liang Hsu, Hsinchu (TW)

Correspondence Address: BACON & THOMAS, PLLC, 625 SLATERS LANE, FOURTH FLOOR, ALEXANDRIA, VA, 22314, US

(73) Assignee: EPISTAR CORPORATION, Hsinchu (TW)

(21) Appl. No.: 11/647,341

(22) Filed: Dec. 29, 2006

(30) Foreign Application Priority Data
Dec. 30, 2005 (TW) 094147863

(51) Int. Cl. H01L 23/053

(52) U.S. Cl. 257/722; 257/701

(57) ABSTRACT

This invention relates to a hybrid composite material substrate. The substrate includes a conductive layer, an insulating layer, and a dispersion material extending from the conductive layer into the insulating layer.

### REFERENCE TO RELATED APPLICATION

The present application claims the right of priority based on Taiwan Application Ser. No. 094147863, filed Dec. 30, 2005, the disclosure of which is incorporated herein by reference in its entirety.

### TECHNICAL FIELD

The present invention relates to a hybrid composite material substrate, and more particularly to a hybrid composite material substrate having two or more matrices and a dispersion material, and an electrical component using the same.

### BACKGROUND

The electrical component inherently generates heat in a higher level along with the larger size of the component and higher level of integration so it usually resides on a substrate having higher thermal conductivity that is aided in heat dissipation. Metal is a conventional high-thermal-conductivity material adopted as the substrate, and characterized by not only high thermal conductivity but also coefficient of thermal expansion (CTE) generally far different from that of electrical component. Accordingly, the electrical component readily separates from the metal substrate after bearing several thermal cycles.

Metal matrix composite (MMC) using carbon fiber as reinforcement material is another choice of substrate material to support the electrical component Carbon fiber is a good conductor of electricity and heat. The filling ratio of carbon fiber contained in the metal substrate can be deliberately controlled to change the CTE of the metal composite material; therefore the difference of the CTEs between the electrical component and the substrate can be reduced to relief the electrical component from the separation problem after several thermal cycles.

Otherwise, some problems still remain for solving when using metal composite material as substrate. For example, electrical component and circuit cabling are not easy to fix or form on the metal matrix composite material, and the character of carbon fiber readily peeling off from the surface of the metal matrix is harmful to surface treatment. Furthermore, complicated manufacturing process is needed to insulate the electrical component from the conductive metal matrix composite material.

### SUMMARY OF THE INVENTION

The hybrid composite material substrate according to an embodiment of the present invention comprises a conductive layer having a first surface and a second surface; an insulating layer overlaying an area of the first surface; and a dispersion material at least passing through the first surface.

According to another embodiment of the present invention, the hybrid composite material substrate further comprises a circuit layer forming on the insulating layer and electrically connecting to an electrical component. In addition, a linking material can be optionally used to attach the circuit layer to the insulating layer

According to a further embodiment of the present invention, the hybrid composite material substrate further comprises a metal layer overlaying at least the second surface of the conductive layer. Moreover, the dispersion material can optionally pass through the second surface.

The hybrid composite material substrate according to an additional embodiment of the present invention further comprises a heat dissipating structure for transmitting thermal energy to an environmental medium, and a thermal conductive layer between the conductive layer and the heat dissipating structure to forward heat from the conductive layer to the heat dissipating structure.

### BRIEF DESCRIPTION OF THE DRAWINGS

FIG. 1 is a cross sectional view of a hybrid composite material substrate according to an embodiment of the present invention.

FIGS. 2A and 2B are cross sectional views of hybrid composite material substrates according to embodiments of the present invention.

FIG. 3 is a cross sectional view of a hybrid composite material substrate according to another embodiment of the present invention.

FIG. 4 is a cross sectional view of a hybrid composite material substrate according to a further embodiment of the present invention.

FIG. 5 is a cross sectional view of a hybrid composite material substrate according to an additional embodiment of the present invention.

### DETAILED DESCRIPTION OF THE PREFERRED EMBODIMENTS

### First Embodiment

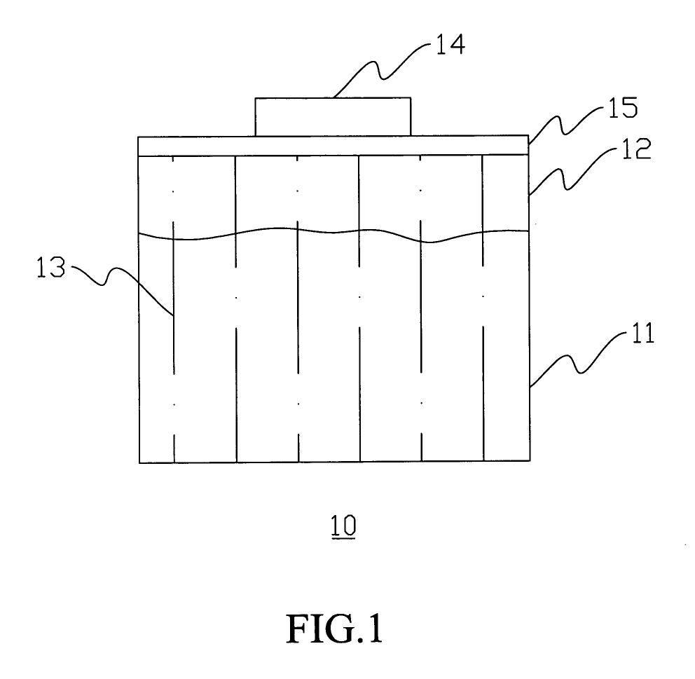

FIG. 1 is a cross sectional view illustrating a hybrid composite material substrate according to an embodiment of the present invention. Hybrid composite material substrate 10 includes a conductive layer 11 and an insulating layer 12. The conductive layer 11 has a first surface to which the insulating layer 12 is attached, and a second surface. A dispersion material 13 to reinforce the structure of the hybrid composite material substrate 10 is contained in the conductive layer 11 and the insulating layer 12, and selected to have a coefficient of thermal expansion (CTE) tending to be smaller than that of the conductive layer 11 or the insulating layer 12. The ratio of the dispersion material 13 contained in the conductive layer 11 and/or the insulating layer 12 can be deliberately controlled to make the hybrid composite material substrate 10 having the coefficient of thermal expansion similar to that of component on or material of the substrate 10.

In the present invention, the dispersion material 13 can be dispersed in the whole or only part of the conductive layer 11 and the insulating layer 12, and, nevertheless, passes through the first surface of the conductive layer 11 in any case. Accordingly, the conductive layer 11 and the insulating layer 12 are tightly joined together with the assistance of the dispersion material 13 that co-exists or continuously extends among them. Furthermore, a roughened first surface can be formed between the conductive layer 11 and the insulating layer 12 to enhance the bonding strength therebetween.

Electrical component 14 can be deployed on a circuit layer 15 supported by the hybrid composite material substrate 10 or directly attached to substrate 10. The circuit layer 15 can be attached to the insulating layer 12 at lower temperature by glue that generally has lower solidification temperature than that of solder, therefore the damages, caused by high temperature during soldering, to the circuit layer 15 or the electrical component 14 thereon can be prevented from. The glue includes but not limited to epoxy, benzocyclobutene (BCB), polyimide, SOG, and silicone. By choice, the circuit layer 15 can be attached to the insulating layer 12 by tape.

The electrical component 14 and the circuit layer 15 are often sensitive to conductive material. But, by the adoption of the insulating layer 12 interposing between the electrical component 14 and the circuit layer 15, the anti-electrostatic property of the electrical component 14 and the circuit layer 15 can be improved, and the insulation design can be simplified.

The circuit layer 15, on which circuit layout is formed to electrically connect to the electrical component 14, includes but not limited to a printed circuit board, flexible printed circuit, Si substrate, and ceramic substrate, and has an additional function to transport thermal energy caused by the operation of the electrical component 14 and current flow to the conductive layer 11 and the insulating layer 12.

The conductive layer 11 must have an adequate thickness to avoid bending and deformation. The insulating layer 12 preferably has a thickness greater than the roughness of the conductive layer 11 while smaller than a value unfavorable to the thermal conducting property. For example, if the matrix of the conductive layer 11 is aluminum, the conductive layer 11 preferably has a thickness greater than 500 μm, and the insulating layer 12 has a thickness smaller than 3 μm and preferable to 2˜3 μm.

The dispersion material 13 contained in the conductive layer 11 and the insulating layer 12 includes but not limited to fiber, particulate, flake, laminate, and any combination thereof. The diameter of the fiber is between 5 μm and 6 μm, provided the dispersion material 13 is carbon fiber. The particulate and fibrous reinforcement material can be introduced into the substrate together while the diameter of the particulate is preferable to smaller than that of the fiber. The volume filling ratio of the dispersion material 13 contained in the conductive layer 11 and/or the insulating layer 12 is greater than 40%, and preferably between 60% and 90%.

The conductive layer 11, which is a conductor of electricity and has an appropriate thermal conductivity, can be made of material including but not limited to Al, Cu, Fe, Ti, Ni, and any alloy thereof.

The insulating layer 12, which has a function to electrically isolate the electrical component 14 and the circuit layer 15 from the conductive layer 11, can be made of macromolecular material or ceramic material. The macromolecular material includes but not limited to polyester, phenolics, epoxy, polyimide, polypropylene, polyethylene, polyamide, polyetheretherketone (PEEK), polytherimide (PEI), polyethersulfone (PES), and polyamideimide (PAI). The ceramic material includes but not limited to Si₃N₄, SiC, ZrO₂, and carbon.

The dispersion material 13 can be made of material including but not limited to Al₂O₃, AlN, SiC, SiO, ZrO₂, Si₃N₄, TiB₂, ZrB₂, Ni—Fe alloy, memory alloy, W, Mo, Si, carbon, B, glass, Ni₃Al, Nb₃Al, and FeAl₃.

### Second Embodiment

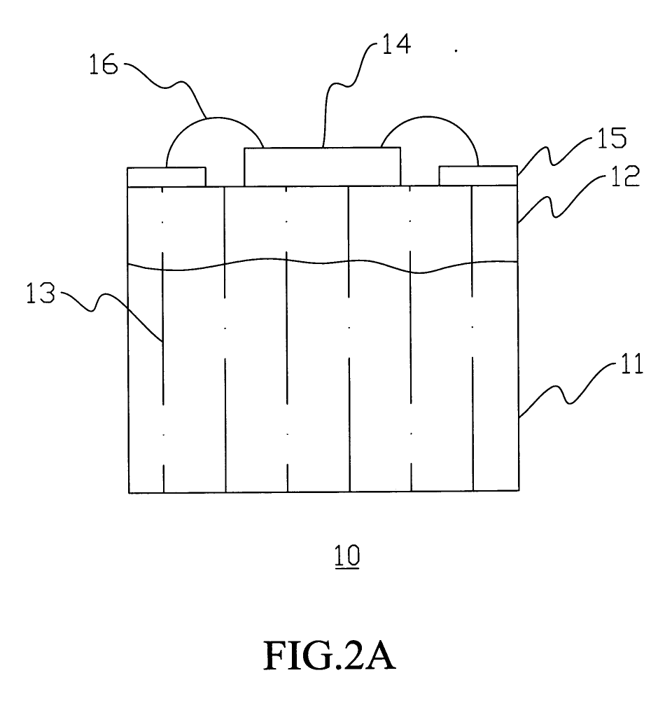

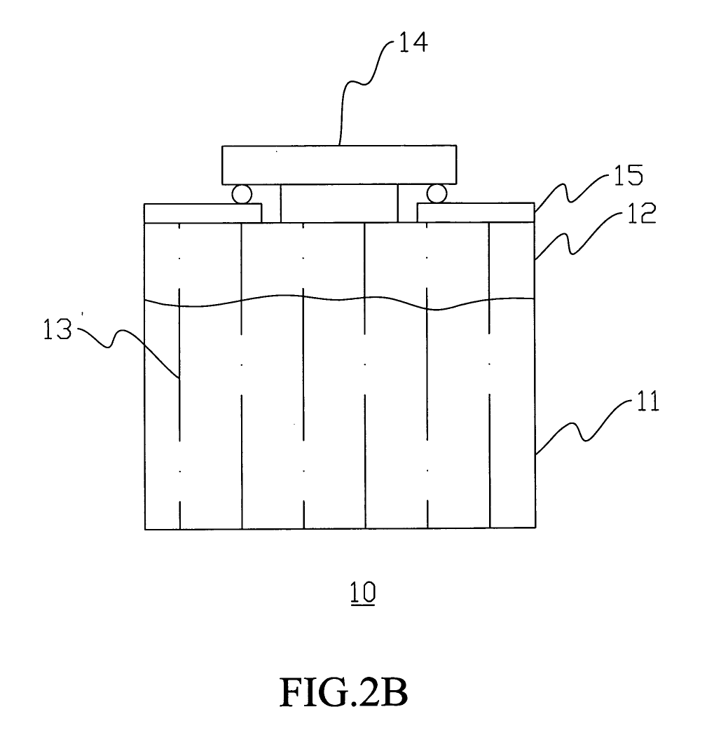

FIGS. 2A and 2B are cross sectional views illustrating hybrid composite material substrates according to embodiments of the present invention. The same reference numbers are used for the elements similar to those describing in the first embodiment, and will not be explained again hereinafter.

In present embodiment, the electrical component 14 is attached to the insulating layer 12 instead of to the circuit layer 15. An opening formed on the circuit layer 15 exposes the insulating layer 12 to directly contact with the electrical component 14. The electrical component 14 can be attached to the insulating layer 12 by good-affinity glue at lower temperature. The material of the glue can be chosen from the same candidates described in the first embodiment.

The electrical connection between the electrical component 14 and the circuit layer 15 can be made by wire 16 or in a flip-chip manner, as shown in FIG. 2B.

### Third Embodiment

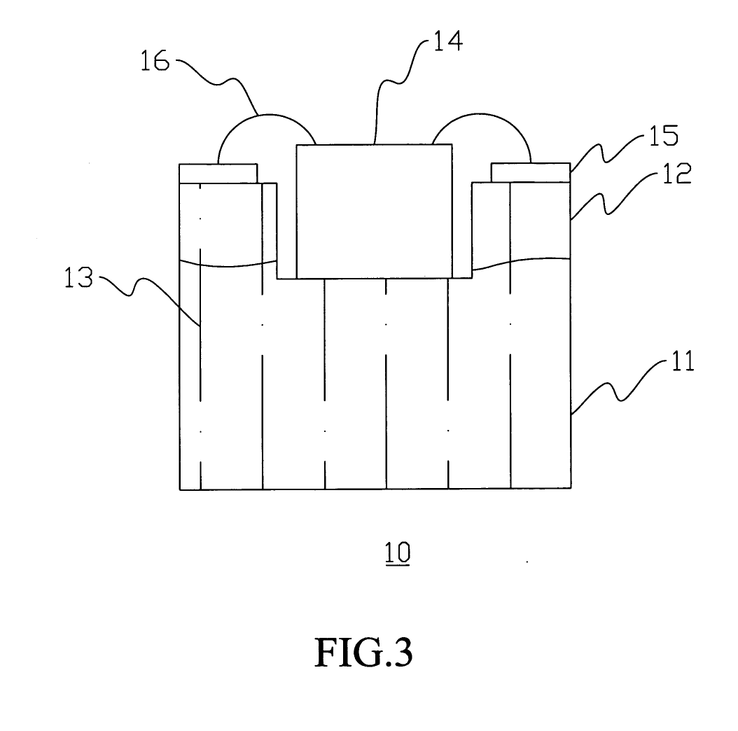

FIG. 3 shows a cross sectional view illustrating a hybrid composite material substrate according to another embodiment of the present invention. The same reference numbers are used for the elements similar to those describing in the first embodiment, and will not be explained again hereinafter.

In present embodiment, the electrical component 14 is attached to the conductive layer 11 instead of to the circuit layer 15. An opening formed on the circuit layer 15 and the insulating layer 12 exposes the conductive layer 11 to directly contact with the electrical component 14. The electrical component 14 can be attached to the insulating layer 12 by good-affinity glue at lower temperature. The electrical connection between the electrical component 14 and the circuit layer 15 can be made by wire 16 or in flip-chip manner as mentioned above, as shown in FIG. 2B. In such case, the electrical component 14 is insulated from the conductive layer 11 by means of such as insulating glue.

### Fourth Embodiment

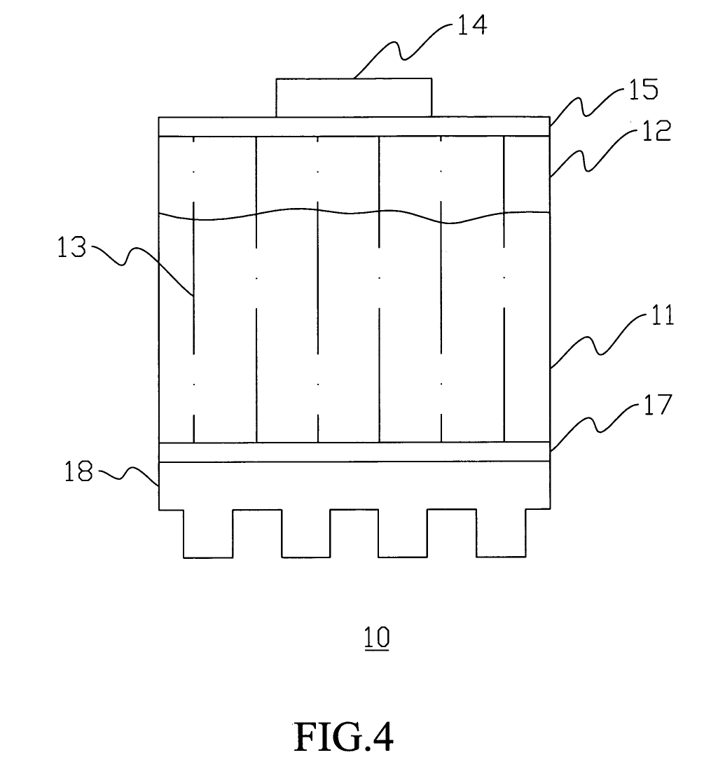

As shown in FIG. 4, a thermal conductive layer 17 is formed on a bottom surface of the conductive layer 11 and associated with a heat dissipating structure 18. The heat dissipating structure 18 functions to lower the temperature of the electrical component 14 and/or the circuit layer 15 by thermal convection with environmental air or other medium. A plurality of cavities, protrusions, or fins are optionally constructed into the heat dissipating structure 18 to increase the contact area with the environmental air or other medium. The dimensions of the plurality of cavities, protrusions, or fins are determined by the thermal output of the system comprised of electrical component, circuit layer and other heat generators, and the size of the heat dissipating structure 18.

Moreover, the heat dissipating structure 18 includes a porous structure made of porous material that has many interconnected pores through which fluid such as air and water can flow. The pores enable the porous structure to create much larger contact area that facilitates the thermal dissipation arose from the thermal convection within the fluid.

The thermal conductive layer 17 can be made of material such as metal or ceramic, and preferably, the same metal, or its alloy, used in the conductive layer 11.

The conductive layer 11 and the thermal conductive layer 17 can be stacked together by using process to manufacture composite material provided using the same metal within them, or soldering. Part of the dispersion material 13 crosses the conductive layer 11 and the thermal conductive layer 17, in other words, passes through the interface or inter-material between the conductive layer 11 and the thermal conductive layer 17. Alternatively, provided adopting an alloy of a metal used in the conductive layer 11, the conductive layer 11 and the thermal conductive layer 17 can be soldered together.

The thermal conductive layer 17 can be made of metal and attached to the heat dissipating structure 18 by solder, glue, and mechanical means. The glue can be chosen from the candidates described in above embodiments. The mechanical means is such as screw, friction fitting, and snap fitting.

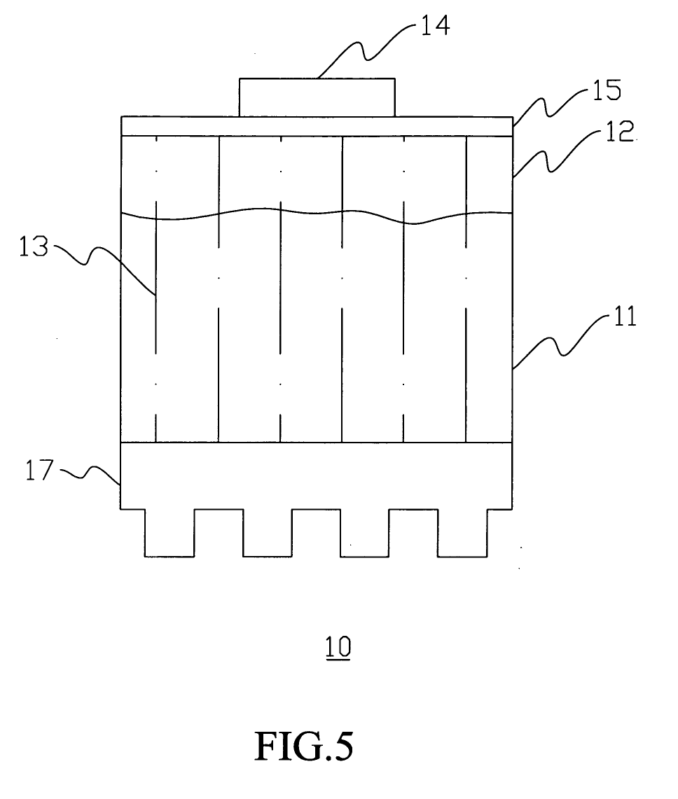

As shown in FIG. 5, a plurality of cavities, protrusions, and fins can be formed in the thermal conductive layer 17 to function as a heat dissipating structure. Specifically, the preferable material to construct the heat dissipating structure is metal while other materials can serve as well.

### Fifth Embodiment

The manufacturing process of hybrid composite material substrate 10 of the present invention is described hereinafter.

Dispersion material 13 such as carbon fiber is prepared in a mold. Melted metal such as aluminum is then poured into the mold to make a metal matrix composite material having opposite first and second surfaces. A protection layer such as silicon oxide is formed on the second surface of the metal matrix composite material to prevent contaminations or damages in following manufacturing steps. An etching process is then carried out to expose part of the dispersion material 13 and form an exposed vacancy on the first surface of the metal matrix composite material. The matrix material such as macromolecular is poured into the exposed vacancy. Finally, the hybrid composite material substrate of the present invention is accomplished after removing the protection layer,

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structures.

What is claimed is:

1. A hybrid composite material substrate comprising:
a conductive layer having a first surface and a second surface;
an insulating layer overlaying an area of said first surface; and
a dispersion material crossing said conductive layer and said insulating layer.

2. The hybrid composite material substrate of claim 1, further comprising:
a circuit layer forming on said insulating layer and electrically connecting to an electrical component.

3. The hybrid composite material substrate of claim 2, further comprising:
a linking material for connecting said circuit layer and said insulating layer.

4. The hybrid composite material substrate of claim 1, further comprising:
a metal layer overlaying at least said second surface of said conductive layer.

5. The hybrid composite material substrate of claim 4, wherein said dispersion material passing through said second surface.

6. The hybrid composite material substrate of claim 4, wherein said metal layer comprises an uneven surface.

7. The hybrid composite material substrate of claim 1, further comprising:
a heat dissipating structure for transmitting thermal energy to an environmental medium; and
a thermal conductive layer, between said conductive layer and said heat dissipating structure, for transferring heat from said conductive layer to said heat dissipating structure.

8. The hybrid composite material substrate of claim 7, wherein said heat dissipating structure is selected from the group consisting of a fin structure, a porous structure, a protrudent structure, an indented structure, and any combination thereof.

9. The hybrid composite material substrate of claim 1, wherein said insulating layer comprises macromolecular material or ceramic material.

10. The hybrid composite material substrate of claim 1, wherein said conductive layer comprises material selected from the group consisting of Al, Cu, Fe, Ti, Ni, and an alloy thereof.

11. The hybrid composite material substrate of claim 1, wherein said insulating layer comprises material selected from the group consisting of polyester, phenolics, epoxy, polyimide, polypropylene, polyethylene, polyamide, polyetheretherketone (PEEK), polytherimide (PEI), polyethersulfone (PES), and polyamideimide (PAI).

12. The hybrid composite material substrate of claim 1, wherein said insulating layer comprises material selected from the group consisting of Si₃N₄, SiC, ZrO₂, and carbon.

13. The hybrid composite material substrate of claim 1, wherein said dispersing material is selected from the group consisting of Al₂O₃, AlN, SiC, SiO, ZrO₂, Si₃N₄, TiB₂, ZrB₂, an Ni-Fe alloy, a memory alloy, W, Mo, Si, carbon, B, glass, Ni₃Al, Nb₃Al, FeAl_{3.}

14. The hybrid composite material substrate of claim 1, wherein said dispersing material is in a form selected from the group consisting of fiber, particulate, flake, and laminate.

15. The hybrid composite material substrate of claim 1, wherein the volume filling ratio of said dispersing material contained in said substrate is in the range of 40˜90%.

16. The hybrid composite material substrate of claim 1, wherein said dispersing material comprises a plurality of fibers having diameters in the range of 5˜6μm.

17. The hybrid composite material substrate of claim 16, further comprising a plurality of particles having diameters smaller than those of said fibers.
